(19) United States
(12) Patent Application Publication
(10) Pub. No.: US 2010/0294543 A1
(43) Pub. Date: Nov. 25, 2010

(54) HEAT DISSIPATING SUBSTRATE AND METHOD OF MANUFACTURING THE SAME

(76) Inventors: Young Ho Sohn, Gyunggi-do (KR); Seog Moon Choi, Seoul (KR); Sung Keun Park, Gyunggi-do (KR); Young Ki Lee, Gyunggi-do (KR); Bum Sik Jang, Gyunggi-do (KR); Ji Hyun Park, Seoul (KR)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 12/539,527

(22) Filed: Aug. 11, 2009

(30) Foreign Application Priority Data
May 21, 2009 (KR) 10-2009-0044687

(51) Int. Cl. H05K 1/00; B05D 5/12

(52) U.S. Cl. 174/252; 427/97.1

(57) ABSTRACT

Disclosed herein is a heat dissipating substrate having a structure in which two two-layered core substrates, each including a metal core functioning to radiate heat, are laminated and connected in parallel to each other, thus accomplishing more improved radiation performance, and a method of manufacturing the same.

### CROSS REFERENCE TO RELATED APPLICATION

This application claims the benefit of Korean Patent Application No. 10-2009-0044687, filed May 21, 2009, entitled “Heat-dissipating substrate and fabricating method of the same”, which is hereby incorporated by reference in its entirety into this application.

### BACKGROUND OF THE INVENTION

1. Technical Field

The present invention relates to a heat dissipating substrate having improved radiation performance and a method of manufacturing the same.

2. Description of the Related Art

Generally, a printed circuit board is manufactured in such a way that one side or both sides of a board made of various thermosetting synthetic resins are coated with copper foil, ICs and electronic components are disposed and fixed on the board, electric wiring is realized therebetween, and then the whole is coated with an insulator.

One of the problems occurring when an electronic circuit is formed on such a printed circuit board using ICs or electronic components is the fact that heat is generated from the ICs or electronic components. That is, when a predetermined voltage is applied to an electronic component, electric current flows therethrough, and thus heat is inevitably generated due to resistance loss. In this case, when heat is slightly generated, the electronic component can be operated without hindrance through only natural air-cooling. However, when heat is generated in abundance, the electronic component cannot smoothly operate using only natural air-cooling, and its temperature continuously increases, so that there are problems in that the electronic component malfunctions and is damaged due to the increase of the temperature thereof and in that the reliability of electronic products is deteriorated.

In order to solve the above problems, various structures for radiating the heat and cooling the electronic component are being proposed. For example, a printed circuit board comprising a heat radiation plate is proposed.

However, this printed circuit board is also problematic in that it cannot appropriately keep up with the trend of the slimness and miniaturization of various electronic products because it must be provided with an additional structure for providing heat radiation. Moreover, this printed circuit board is problematic in that its production cost increases and it easily breaks down because it includes the additional structure.

Therefore, in order to increase the heat radiation efficiency of the printed circuit board without generating such problems, methods of increasing heat radiation efficiency by embedding a metal plate having high thermal conductivity into a printed circuit board instead of providing an additional structure in the printed circuit board are being proposed.

FIGS. 1 to 6 are sectional views showing a process of manufacturing a conventional multilayered printed circuit board including a metal plate for heat radiation. This process is described as follows with reference to FIGS. 1 to 6.

First, as shown in FIG. 1, through-holes 2 are formed in a metal core 1 having high thermal conductivity using a CNC drill.

Subsequently, as shown in FIG. 2, an insulation material layer 3 and a copper foil layer 4 are sequentially formed on both sides of the metal core 1.

Subsequently, as shown in FIG. 3, via holes 5 for interlayer connection are formed in the through-holes 2 of the metal core 1 through a mechanical process. Here, the via holes 5 must be formed such that the size of each of the via holes 5 is smaller than that of each of the through-holes 2 of the metal core 1 in order to isolate copper plating layers in the inner walls of the via holes 5 from each other.

Subsequently, as shown in FIG. 4, copper plating layers are formed on the inner walls of the via holes 5 through a chemical copper plating process, that is, an electroless copper plating process and an electrolytic copper plating process for the interlayer connection, and an inner circuit pattern 6 is formed thereon through exposure, development and etching processes.

Subsequently, as shown in FIG. 5, insulation layers 7a and 7b and a circuit layer 8 are formed through a build-up process to form desired outer layers.

Finally, as shown in FIG. 6, a solder resist layer 9 having openings is formed on the surface of the outer layer in order to protect the outer layer, thereby manufacturing a multilayered printed circuit board.

In the conventional multilayered printed circuit board, its heat radiation efficiency is improved by inserting therein a metal core having high thermal conductivity.

However, in the conventional multilayered printed circuit board, the heat radiation thereof is attempted by inserting a metal core thereinto, but it is difficult to sufficiently radiate the heat generated therefrom using only the metal core.

### SUMMARY OF THE INVENTION

Accordingly, the present invention has been made to solve the above-mentioned problems, and the present invention provides a heat dissipating substrate having improved radiation performance and a method of manufacturing the same.

An aspect of the present invention provides a heat dissipating substrate, including: an insulator; a first core substrate which is provided on one side of the insulator and includes a first metal core in which a first via hole and a first through hole are formed, a first anodized insulation film formed on a surface of the first metal core and on inner walls of the first via hole and the first through hole, and a first circuit layer formed on the first anodized insulation film; and a second core substrate which is provided on the other side of the insulator such that it is electrically connected with the first core substrate and includes a second metal core in which a second via hole and a second through hole are formed, a second anodized insulation film formed on a surface of the second metal core and on inner walls of the second via hole and the second through hole, and a second circuit layer formed on the second anodized insulation film.

Here, the insulator between the first through-hole and the second through-hole may be removed to form all layer through-hole integrated with the first through-hole and the second through-hole, and the all layer through-hole may be charged with a conductive material to electrically connect the first circuit layer of the first core substrate with the second circuit layer of the second core substrate.

Further, the conductive material may be a plating layer or conductive paste formed in the all layer through-hole.

Further, the metal core may be made of aluminum or aluminum alloy.

Further, the anodized insulation film may be an aluminum anodized insulation film (Al₂O₃).

Another aspect of the present invention provides a method of manufacturing a heat dissipating substrate, including: preparing a first core substrate which includes a first metal core in which a first via hole and a first through hole are formed, a first anodized insulation film formed on a surface of the first metal core and on inner walls of the first via hole and the first through hole, and a first circuit layer formed on the first anodized insulation film; preparing a second core substrate which includes a second metal core in which a second via hole and a second through hole are formed, a second anodized insulation film formed on a surface of the second metal core and on inner walls of the second via hole and the second through hole, and a second circuit layer formed on the second anodized insulation film; disposing the first core substrate and the second core substrate such that the first through-hole and the second through-hole are aligned with each other and then attaching the first core substrate and second core substrate to each other using an insulator; removing the insulator charged in the first and second through-holes and present between the first and second through-holes to all layer through-hole; and plating or charging a conductive material in the all layer through-hole to connect the first circuit layer of the first core substrate with the second circuit layer of the second core substrate.

In this case, the metal core may be made of aluminum or aluminum alloy.

Further, the anodized insulation film may be an aluminum anodized insulation film (Al₂O₃).

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

### BRIEF DESCRIPTION OF THE DRAWINGS

The above and other objects, features and advantages of the present invention will be more clearly understood from the following detailed description taken in conjunction with the accompanying drawings, in which:

FIGS. 1 to 6 are sectional views showing a process of manufacturing a conventional multilayered printed circuit board including a metal plate for heat radiation;

FIG. 7 is a sectional view showing a heat dissipating substrate according to an embodiment of the present invention;

FIGS. 8 to 15 are sectional views showing a process of manufacturing the heat dissipating substrate according to an embodiment of the present invention.

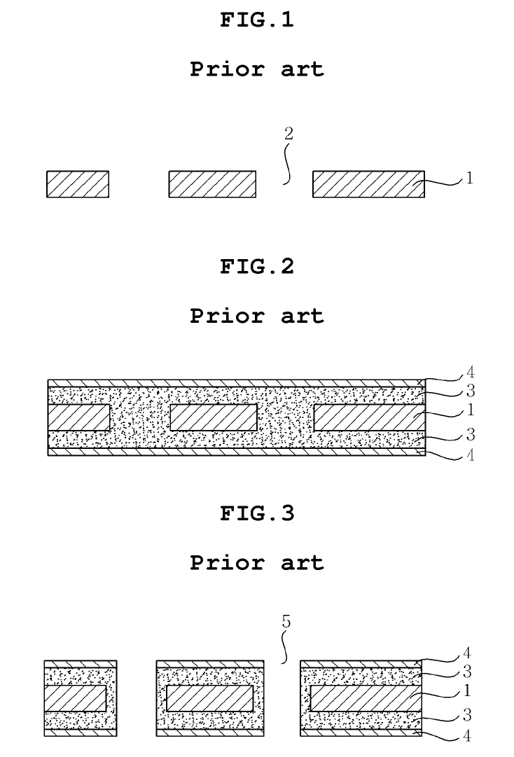

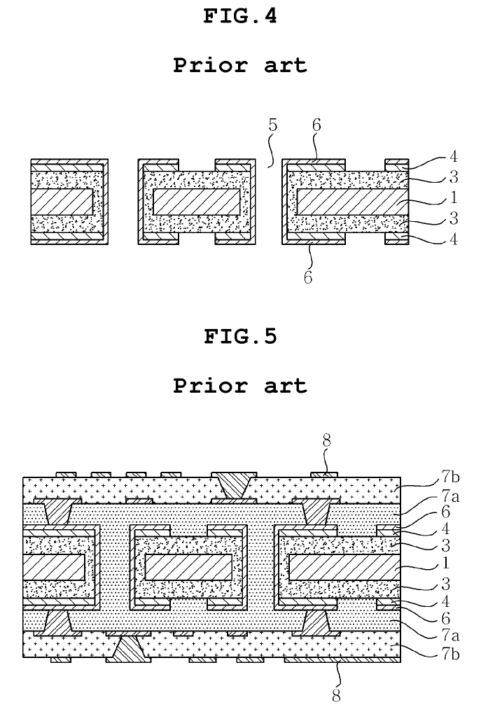

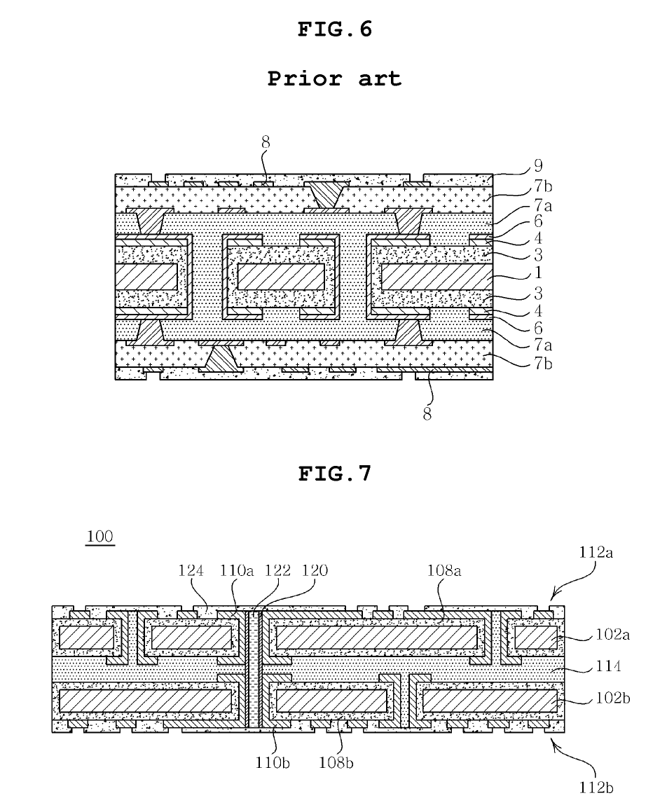

### DESCRIPTION OF THE PREFERRED EMBODIMENTS

The objects, features and advantages of the present invention will be more clearly understood from the following detailed description and preferred embodiments taken in conjunction with the accompanying drawings. Throughout the accompanying drawings, the same reference numerals are used to designate the same or similar components, and redundant descriptions thereof are omitted. In the description of the present invention, when it is determined that the detailed description of the related art obscures the gist of the present invention, the description thereof will be omitted.

Hereinafter, preferred embodiments of the present invention will be described in detail with reference to the attached drawings.

A Structure of a Heat Dissipating Substrate

FIG. 7 is a sectional view showing a heat dissipating substrate according to an embodiment of the present invention. Hereinafter, a heat dissipating substrate 100 according to an embodiment of the present invention will be described with reference to FIG. 7.

As shown in FIG. 7, the heat dissipating substrate 100 according to an embodiment of the present invention has a structure in which two core substrates 112a and 112b, each of which has a metal core, are formed on both sides of an insulator 114.

Among the core substrates 112a and 112b, the first core substrate 112a is provided on one side of the insulator 114 and includes a first metal core 102a in which a first via hole 104a and a first through hole 106a are formed, a first anodized insulation film 108a formed on the surface of the first metal core 102a and on the inner walls of the first via hole 104a and the first through hole 106a, and a first circuit layer 110a formed on the first anodized insulation film 108a, and the second core substrate 112b is provided on the other side of the insulator 114 such that it is electrically connected with the first core substrate 112a and includes a second metal core 102b in which a second via hole 104b and a second through hole 106b are formed, a second anodized insulation film 108b formed on the surface of the second metal core 102b and on the inner walls of the second via hole 104b and the second through hole 106b, and a second circuit layer 110b formed on the second anodized insulation film 108b.

In this case, the first core 112a and the second core substrate 112b are electrically connected with each other by removing the insulator 114 between the first through-hole 106a and the second through-hole 106b to form all layer through-hole 118 and then charging the all layer through-hole 118 with a conductive material 120. Here, the conductive material 120 may be a plating layer or conductive paste formed on the inner wall of the all layer through-hole 118.

Further, the first metal core 102a and second metal core 102b are easily available at comparatively low cost, have very excellent heat transfer characteristics, and are made of an anodizable metal, for example, aluminum (Al) or aluminum alloy.

Further, the first anodized insulation film 108a and second anodized insulation film 108b may be an aluminum anodized insulation film (Al₂O₃) having a comparatively high transfer characteristic of 10˜30 W/mK.

A Method of Manufacturing a Heat Dissipating Substrate

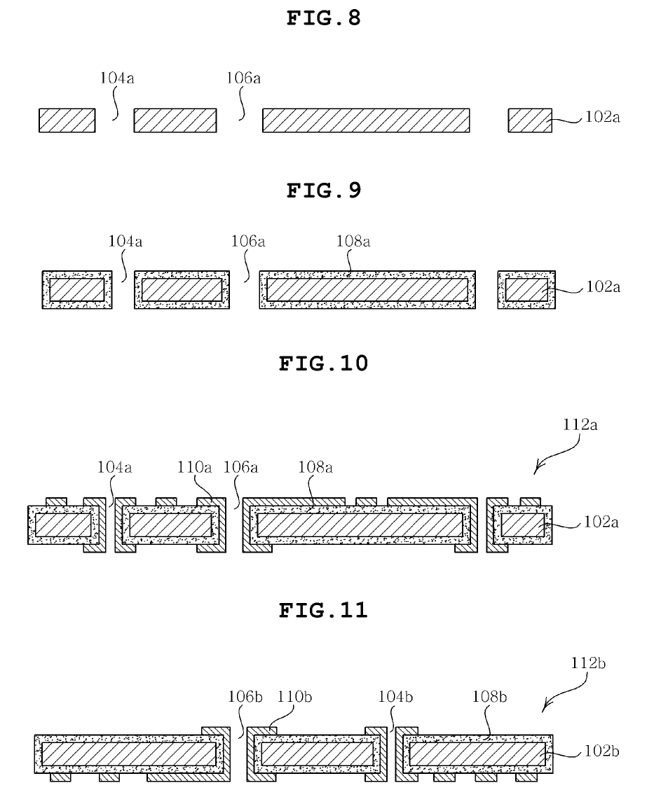

FIGS. 8 to 15 are sectional views showing a method of manufacturing a heat dissipating substrate according to an embodiment of the present invention. The method of manufacturing a heat dissipating substrate according to an embodiment of the present invention is characterized in that two two-layered core substrates, each of which includes a metal core on which an anodized insulation film is formed, are prepared, and then the two core substrates are attached to both sides of an insulator to be connected with each other, thus manufacturing a four-layered heat dissipating substrate. Although a method of manufacturing a four-layered heat dissipating substrate is described as follows, multi-layered heat dissipating substrates having more layers, for example, a six-layered heat dissipating substrate, eight-layered heat dissipating substrate and the like, can also be manufactured based on the same principle as that of the four-layered heat dissipating substrate. Hereinafter, a method of manufacturing a heat dissipating substrate according to an embodiment of the present invention will be described in detail with reference to FIGS. 8 to 15.

First, as shown in FIG. 8, a first via hole 104a and a first through-hole 106a are formed in a first metal core 102a.

Here, the first via hole 104a is used to interconnect circuit layers of a first core substrate 112a, and the first through-hole 106a is used to interconnect the first core substrate 112a and a second core substrate 112b.

The first via hole 104a and first through-hole 106a are formed using a CNC (computer numeric controlled) drill or a laser (for example, a CO₂ laser or a YAG laser).

In this case, the used first metal core 102a is easily available at comparatively low cost, has very excellent heat transfer characteristics, and is made of an anodizable metal, for example, aluminum (Al) or aluminum alloy.

Subsequently, as shown in FIG. 9, a first anodized insulation film 108a is formed on the entire surface of the first metal core 102a.

Here, the first anodized insulation film 108a is formed through an anodizing process. Specifically, the first anodized insulation film 108a is formed by immersing the first metal core 102a into an electrolyte, such as boric acid, phosphoric acid, sulfuric acid, chromic acid or the like, and then applying an anode to the first metal core 102a and applying a cathode to the electrolyte.

In this case, the first anodized insulation film 108a may be an aluminum anodized insulation film (Al₂O₃) having a comparatively high transfer characteristic of 10˜30 W/mK.

In the present invention, since a first anodized insulation film 108a, which is thinner and has more excellent heat transfer characteristics than a conventional insulatior, is employed, the thickness of a heat dissipating substrate can be decreased, and the heat radiation efficiency thereof can be increased.

Subsequently, as shown in FIG. 10, a plating layer is formed on the first metal core 102a coated with the first anodized insulation film 108a through a plating process (an electroless copper plating process and an electrolytic copper plating process), and then the plating layer is formed into a first circuit layer 110a through a patterning process, thereby preparing a first core substrate 112a.

In this case, the first circuit layer 110a is formed by disposing a dry film on the plating layer, forming openings in the dry film through exposure and development processes and then etching the plating layer exposed through the openings.

Subsequently, as shown in FIG. 11, a second core substrate 112b, in which a second circuit layer 110b is formed on a second metal core 102b in which a second via hole 104b and a second through hole 106b are formed and a second anodized insulation film 108b is formed on the surface of the second metal core 102b and on the inner walls of the second via hole 104b and the second through hole 106b, is prepared.

In this case, since the second core substrate 112b can be prepared using the same method as the method of preparing the first core substrate 112a shown in FIGS. 8 to 10, the duplicate description thereof will be omitted.

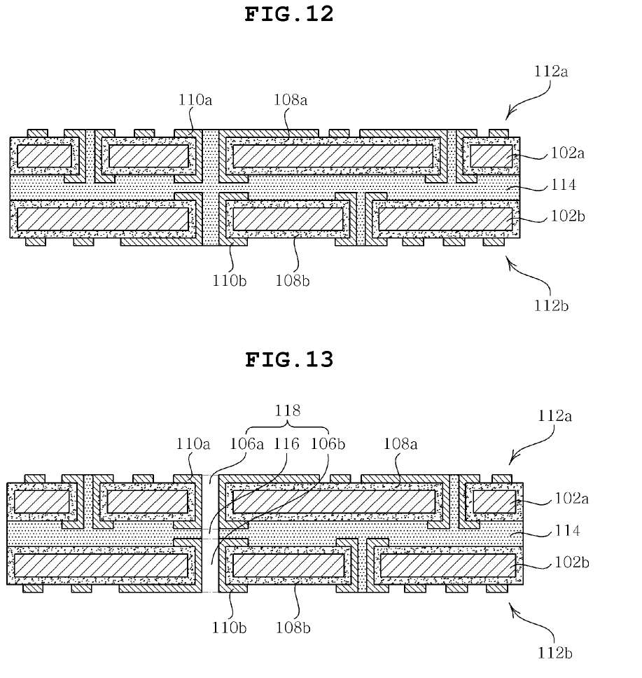

Subsequently, as shown in FIG. 12, the first core substrate 112a and the second core substrate 112b are disposed on both sides of an insulator 114 such that the first through-hole 106a of the first core substrate 112a and the second through-hole 106b of the second core substrate 112a are aligned with each other, and are then pressed to attach the first core substrate 112a and second core substrate 112b to each other.

Here, when the first core substrate 112a and second core substrate 112b are pressed, the semi-cured insulator 114 is embedded and charged in the first and second via holes 104a and 104b and the first and second through-holes 106a and 106b of the first and second core substrates 112a and 112b. In particular, since the insulator 114 embedded and charged in the first and second via holes 104a and 104b can serve as plugging ink, it is not required to additionally charge a filler for improving reliability in the first and second via holes 104a and 104b during subsequent processes. However, when the insulator 114 is not completely charged in the first and second via holes 104a and 104b, additional plugging ink may be charged therein during subsequent processes.

Subsequently, as shown in FIG. 13, the insulator 114 charged in the first and second through-holes 106a and 106b and present between the first and second through-holes 106a and 106b is removed.

Here, the insulator 114 can be removed through a drilling work, thus forming all layer through-hole 118 integrated with the first and second through-holes 106a and 106b.

Meanwhile, for the convenience of explanation, of the all layer through-hole 118, a through-hole region formed by removing the insulator 114 located between the first and second through-holes 106a and 106b is referred to as a third through-hole 116.

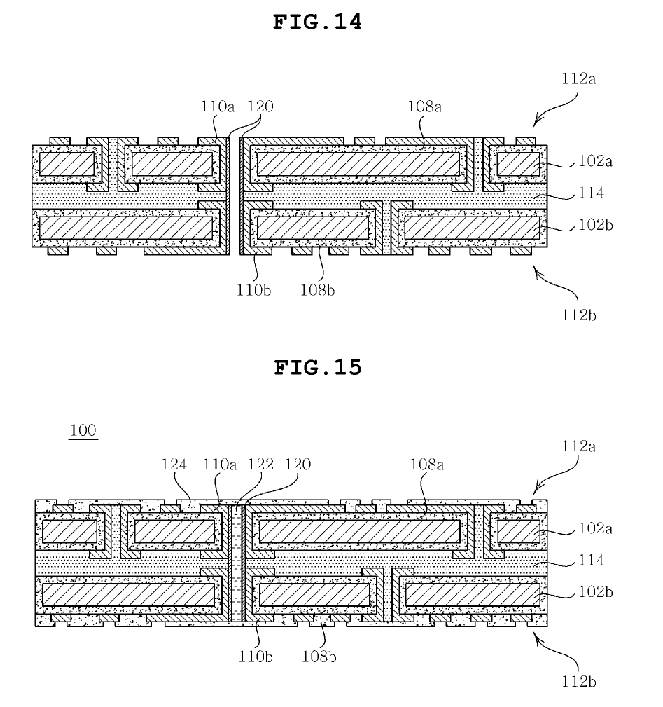

Subsequently, as shown in FIG. 14, a plating layer or a conductive material, such as conductive paste, is plated or charged on the inner wall of the all layer through-hole 118 or in the inner portion thereof, thus connecting the first circuit layer 110a of the first core substrate 112a with the second circuit layer 110b of the second core substrate 112b.

For example, the first circuit layer 110a of the first core substrate 112a can be connected with the second circuit layer 110b of the second core substrate 112b by sputtering the conductive material 120 on the inner wall of the all layer through-hole 118.

However, the method shown in FIG. 14 is an example of methods of connecting the first circuit layer 110a with the second circuit layer 110b. In addition to this method, various methods, such as forming all layer via in the all layer through-hole 118 through a plating process, charging conductive paste in the all layer through-hole 118 and the like, can be applied. These various methods also belong to the scope of the present invention. In this case, plugging ink may be charged in the all layer through-hole 118.

Finally, as shown in FIG. 15, a solder resist layer 124 having openings for exposing pads is formed on the first circuit layer 110a of the first core substrate 112a and the second circuit layer 110b of the second core substrate 112b.

Through the above processes, a four-layered heat dissipating substrate 100 having two metal cores 102a and 102b is manufactured.

As described above, according to the present invention, a four-layered heat dissipating substrate is manufactured by laminating two two-layered core substrates, each including a metal core, so that the four-layered heat dissipating substrate includes two metal cores, thereby improving the radiation performance thereof.

Further, according to the present invention, the thickness of a heat dissipating substrate can be decreased because a circuit layer is formed by forming an anodized insulation film on a metal core, and the radiation performance thereof can be improved because the anodized insulation film has higher thermal conductivity than a general insulation material.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

Simple modifications, additions and substitutions of the present invention belong to the scope of the present invention, and the specific scope of the present invention will be clearly defined by the appended claims.

What is claimed is:

1. A heat dissipating substrate, comprising:
an insulator;
a first core substrate which is provided on one side of the insulator and includes a first metal core in which a first via hole and a first through hole are formed, a first anodized insulation film formed on a surface of the first metal core and on inner walls of the first via hole and the first through hole, and a first circuit layer formed on the first anodized insulation film; and
a second core substrate which is provided on the other side of the insulator such that it is electrically connected with the first core substrate and includes a second metal core in which a second via hole and a second through hole are formed, a second anodized insulation film formed on a surface of the second metal core and on inner walls of the second via hole and the second through hole, and a second circuit layer formed on the second anodized insulation film.

2. The heat dissipating substrate according to claim 1, wherein the insulator between the first through-hole and the second through-hole is removed to form all layer through-hole integrated with the first through-hole and the second through-hole, and the all layer through-hole is charged with a conductive material to electrically connect the first circuit layer of the first core substrate with the second circuit layer of the second core substrate.

3. The heat dissipating substrate according to claim 2, wherein the conductive material is a plating layer or conductive paste formed in the all layer through-hole.

4. The heat dissipating substrate according to claim 1, wherein the metal core is made of aluminum or aluminum alloy.

5. The heat dissipating substrate according to claim 1, wherein the anodized insulation film is an aluminum anodized insulation film (Al₂O₃).

6. A method of manufacturing a heat dissipating substrate, comprising:
preparing a first core substrate which includes a first metal core in which a first via hole and a first through hole are formed, a first anodized insulation film formed on a surface of the first metal core and on inner walls of the first via hole and the first through hole, and a first circuit layer formed on the first anodized insulation film;
preparing a second core substrate which includes a second metal core in which a second via hole and a second through hole are formed, a second anodized insulation film formed on a surface of the second metal core and on inner walls of the second via hole and the second through hole, and a second circuit layer formed on the second anodized insulation film;
disposing the first core substrate and the second core substrate such that the first through-hole and the second through-hole are aligned with each other and then attaching the first core substrate and second core substrate to each other using an insulator;
removing the insulator charged in the first and second through-holes and present between the first and second through-holes to all layer through-hole; and
plating or charging a conductive material in the all layer through-hole to connect the first circuit layer of the first core substrate with the second circuit layer of the second core substrate.

7. The method of manufacturing a heat dissipating substrate according to claim 6, wherein the metal core is made of aluminum or aluminum alloy.

8. The method of manufacturing a heat dissipating substrate according to claim 6, wherein the anodized insulation film is an aluminum anodized insulation film (Al₂O₃).
